(19) United States
(12) Patent Application Publication
(10) Pub. No.: US 2018/0331312 A1
(43) Pub. Date: Nov. 15, 2018

(54) ELECTROLUMINESCENT DEVICE, PREPARATION METHOD THEREOF, AND INK FORMULATION

(71) Applicant: GUANGZHOU CHINARAY OPTOELECTRONIC MATERIALS LTD., Guangzhou (CN)

(72) Inventors: Junyou PAN, Guangzhou (CN); Jiahui TAN, Guangzhou (CN); Hong HUANG, Guangzhou (CN); Xiaolin YAN, Guangzhou (CN)

(21) Appl. No.: 15/773,559

(22) PCT Filed: Sep. 26, 2016
(86) PCT No.: PCT/CN2016/100165

§ 371 Date: May 4, 2018

(30) Foreign Application Priority Data
Nov. 4, 2015 (CN) 201510889778.7

(51) Int. Cl. H01L 51/50; H01L 51/52; H01L 51/00; C09D 11/38; C09D 11/102; C09D 11/033

(52) U.S. Cl. CPC H01L 51/502; H01L 51/5004; H01L 51/5206; H01L 51/5221; H01L 51/0005; H01L 51/5056; C09D 11/38; C09D 11/102; C09D 11/033; H01L 51/5072; H01L 51/0035

(57) ABSTRACT

An electroluminescent device and a preparation method thereof are provided. The electroluminescent device comprises an anode (102), a cathode (106) and a light emitting layer (104) located therebetween. The light emitting layer (104) contains an inorganic luminescent nanomaterial and a polyimide polymer, wherein the HOMO energy level of the polyimide polymer and the valence band energy level V_{B} of the inorganic luminescent nanomaterial satisfy the condition of: V_{B} (inorganic luminescent nanomaterial) ≤HOMO(polyimide)+0.3 eV, thus providing a solution for electroluminescent devices with high-performance that may be easily processed in large area. An ink formulation comprising the luminescent nanomaterial and the polyimide polymer is also provided.

### CROSS-REFERENCE TO RELATED APPLICATIONS

This application is a National Stage of International Application No. PCT/CN2016/100165, filed on Sep. 26, 2016, which claims priority to Chinese application 201510889778.7, filed Nov. 4, 2015, both of which are hereby incorporated by reference in their entireties.

### TECHNICAL FIELD

The present disclosure relates to an electroluminescent device including a luminescent nanomaterial, especially to a quantum dot electroluminescent device containing a mixture that includes a quantum dot and a polyimide. The present disclosure further relates to an ink formulation including the luminescent nanomaterial and the polyimide, a printing method of the ink formulation, and an application of the ink formulation in an optoelectronic device, especially in the electroluminescent device.

### BACKGROUND

Lighting and display is requisite in human society, even it consumes the nature energy to a great extent. Therefore, people are constantly seeking new energy-saving and environment friendly technologies. Among all the new technologies, light emitting diode (LED) is gradually substituting the traditional lighting material and becoming next generation of light source due to its advantages such as energy conservation, environment friendly, durability, and etc. However, the thin film deposition in commercial LED production process has strict requirements on vacuum conditions, which increase the product cost significantly, also is not suitable for production in large areas on flexible substrate. As a new generation of lighting and display technology, organic light emitting diode (OLED) technology can be easily prepared in large area, but the lifetime of the device should be improved. Meanwhile, the full width at half maxima (FWHM) of the electroluminescence spectrum of OLED is over more than 40 nm, which is adverse to display application. Furthermore, OLED has efficiency roll-off and lifetime issues in high luminance, which also limit the application in the solid state lighting.

A colloidal quantum dot (QD) is a solution processible semiconductor nano-crystal with size tunable optical property. The emission wavelength of quantum dot can be adjusted in all visible wave range by changing the size or the component of quantum dot. Meanwhile, the FWHM of the luminescence spectrum of the quantum dot is generally smaller than 30 nm, which is advantage for high color gamut display and high color rendering index lighting. Furthermore, quantum dot light emitting diode (QLED) can be prepared on flexible substrate by a solution process in large area, thereby greatly decreasing the production cost. Therefore, quantum dot light emitting diode (QLED) using the quantum dot in the light emitting layer has the great potential to be the next generation of light source in display and the solid state lighting.

At present, the highest occupied molecular orbital (HOMO) energy level of a common organic hole transport material in the quantum dot light emitting diode (QLED) is generally higher than −5.6 eV. The valence band energy level of the quantum dot is commonly in a range from −6.0 eV to −7.0 eV, so the hole injection efficiency is relatively low because of the unmatched energy level between the organic hole transport material and the quantum dot, then the holes injected to the quantum dot are unbalanced which causes quantum dot non-electroneutral, then the QLED luminous efficiency is greatly decreased. Meanwhile, in the common OLED device, the light emitting layer is consisted of QD, and its thickness is very thin, which is a great challenge to the printing technology. To improve the processibility, a mixture of a polymer and the quantum dot are used in the light emitting layer. For example, a CdSe/ZnS quantum dot is doped into PVK or PFO, which is reported in articles App. Phys. Lett. 2007, 91, 243114 and App. Phys. Lett. 2008, 92, 043303. However, the PVK and the PFO are unstable, which greatly limit the performances of the QLED, especially the lifetime.

Therefore, it is particularly important to find a suitable material formulation of the light emitting layer to improve the performances of the QLED, especially the lifetime.

### SUMMARY

An object of the present disclosure is to provide an electroluminescent device to solve the above described problems of the light emitting layer material of the quantum dot light emitting diode in prior art. The electroluminescent device comprises an anode, a light emitting layer, and a cathode, wherein the light emitting layer is located between the anode and the cathode and includes an inorganic luminescent nanomaterial and a polyimide polymer.

In some embodiments of the present disclosure, the polyimide polymer comprises a repeating unit represented by general formula (I):

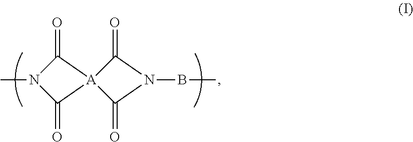

wherein A represents a tetravalent aromatic group or aliphatic group, and B represents a bivalent aromatic group or aliphatic group.

In some embodiments of the present disclosure, the polyimide polymer comprises a repeating unit represented by general formula (II):

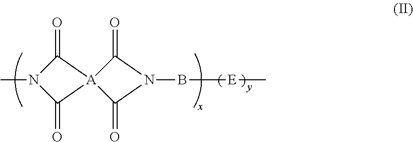

wherein A represents a tetravalent aromatic group or aliphatic group, B represents a bivalent aromatic group or aliphatic group, E is a group having an electron transport ability, and x+y=1.

In some embodiments of the present disclosure, A, in multiple occurrences in the polyimide polymer, is identically or differently selected from the following groups and may be further substituted:

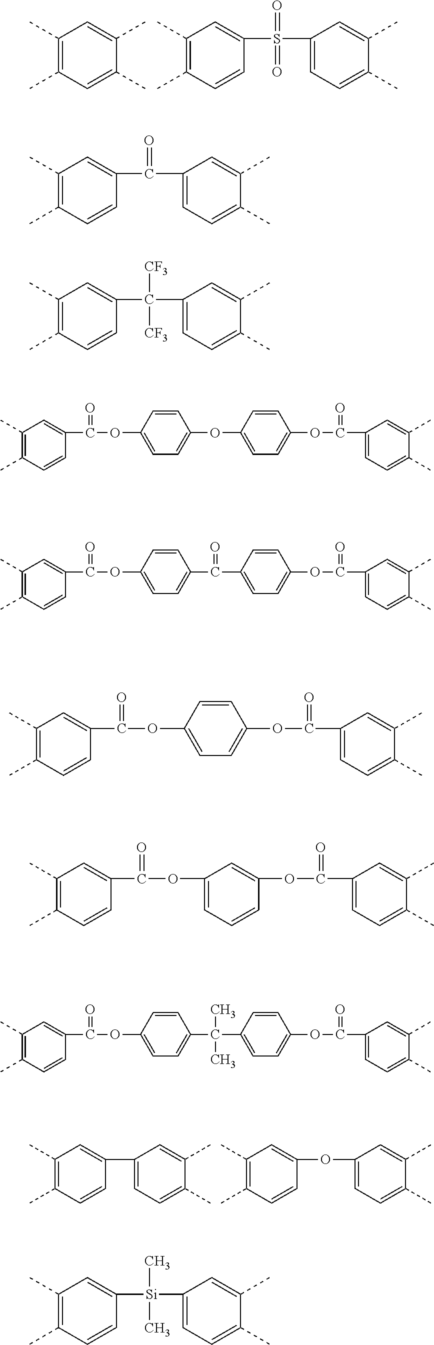

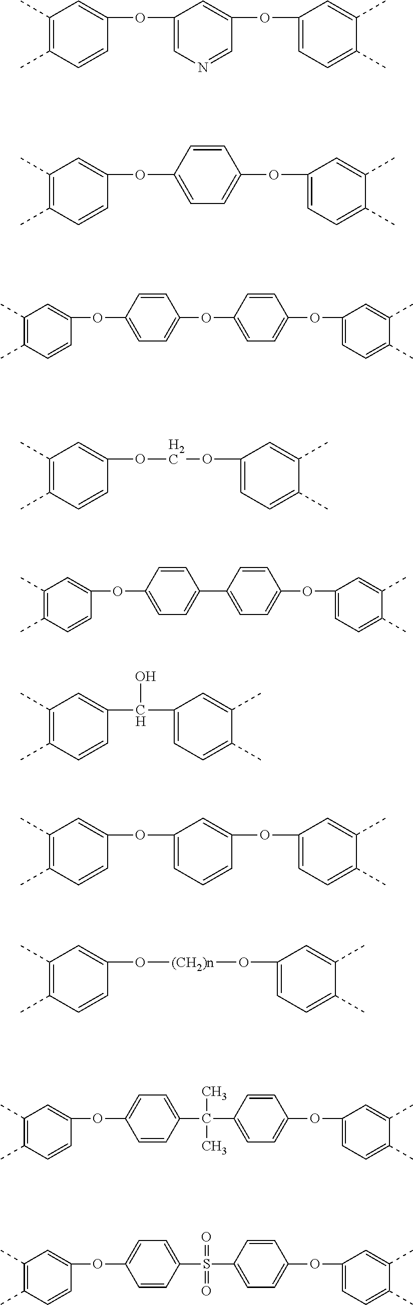

wherein the dashed line bond represents a bond linked with an adjacent structure unit.

In some embodiments of the present disclosure, B, in multiple occurrences in the polyimide polymer, is identically or differently selected from the following groups and may be further substituted:

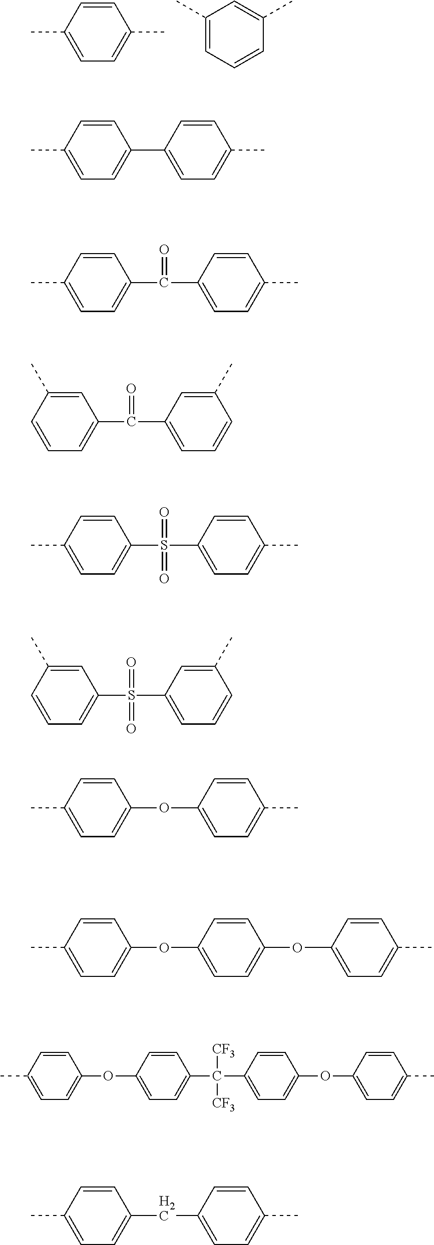

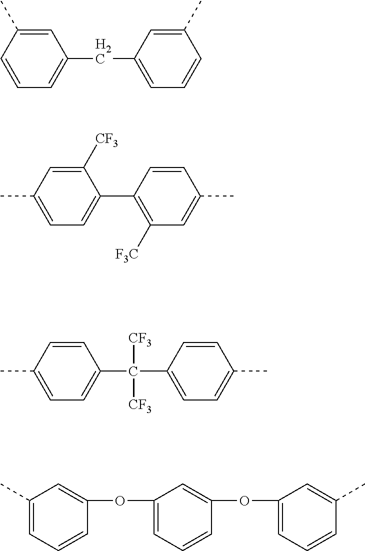

wherein the dashed line bond represents a bond linked with an adjacent structure unit.

In some embodiments of the present disclosure, E is selected from phenazine, phenanthroline, anthracene, phenanthrene, fluorene, bifluorene, spiro-bifluorene, p-phenylenevinylene, pyridazine, pyrazine, triazine, triazole, imidazole, quinoline, isoquinoline, quinoxaline, oxazole, isoxazole, oxadiazole, thiadiazole, pyridine, pyrazol, pyrrole, pyrimidine, acridine, pyrene, perylene, trans-indenofluorene, cis-indenofluorene, dibenzol-indenofluorene, indenonaphthalene, benzanthracene, azaphosphole, azaborole, aromatic ketone, lactam and derivatives thereof.

In some embodiments of the present disclosure, the HOMO energy level of the polyimide polymer is smaller than or equal to −5.6 eV.

In some embodiments of the present disclosure, the HOMO energy level of the polyimide polymer and the valence band energy level of the inorganic luminescent nanomaterial V_{B} satisfy: V_{B}≤HOMO+0.3 eV.

In some embodiments of the present disclosure, the emission wavelength of the inorganic luminescent nanomaterial is in a range from 380 nm to 2500 nm.

In some embodiments of the present disclosure, the emission peak wavelength of the inorganic luminescent nanomaterial is greater than the emission peak wavelength of the polyimide polymer.

In some embodiments of the present disclosure, the inorganic luminescent nanomaterial is a quantum dot material with the monodispersed particle size distribution whose shape is selected from spherical nano-morphology, cubic nano-morphology, rodlike nano-morphology, or branched nano-morphology.

In some embodiments of the present disclosure, the inorganic luminescent nanomaterial is a binary semiconductor compound or a multinary semiconductor compound of Group IV, Group II-VI, Group II-V, Group III-V, Group Group IV-VI, Group Group II-IV-VI, or Group II-IV-V of the Periodic Table of the Elements, or mixtures thereof.

In some embodiments of the present disclosure, the inorganic luminescent nanomaterial is a luminescent perovskite nano-particle material, a metal nano-particle material, a metal oxide nano-particle material, or mixtures thereof.

In some embodiments of the present disclosure, the doping ratio of the inorganic luminescent nanomaterial to the polyimide polymer is in a range from 1:99 to 99:1.

In some embodiments of the present disclosure, the electroluminescent device is selected from quantum dot light emitting diode, quantum dot light emitting electrochemical cell, quantum dot light emitting field effect transistor, or quantum dot laser.

Another object of the present disclosure is to provide an ink formulation comprising the inorganic luminescent nanomaterial, the polyimide polymer, and at least one organic solvent.

In some embodiments of the present disclosure, the light emitting layer is prepared by a printing or coating method, the printing or coating method is selected from inkjet printing, spray printing, typographic printing, screen printing, dip coating, spin coating, blade coating, roller printing, torsion roller printing, lithographic printing, flexographic printing, rotary printing, spray coating, brush coating, transfer printing, or slot die coating.

Beneficial effects: the light emitting layer of the electroluminescent device of the present disclosure comprises the inorganic luminescent nanomaterial and the polyimide polymer, wherein the HOMO energy level of the polyimide polymer is between the HOMO energy level of the organic hole transport layer and the valence band energy level of the quantum dot material, which decreases the operating voltage of the device, increases the luminous efficiency, and improves the processibility of the device, therefore provides a technical solution to prepare high performance quantum dot luminescent device at low cost. The present disclosure further provides a new type polyimide polymer with the improved electron transport ability.

### BRIEF DESCRIPTION OF THE DRAWINGS

FIG. 1 is a cross-sectional schematic structural view of an electroluminescent device of the present disclosure.

FIG. 2 is a spectrum curve of quantum dot light emitting diode according to one example of the present disclosure.

### DETAILED DESCRIPTION

The present disclosure provides an electroluminescent device. In order to make the objects, technical solutions and advantages of the present disclosure to be understood more clearly, the present disclosure will be described in further details. It should be understood that the specific embodiments described herein are merely examples to illustrate the present disclosure, not to limit the present disclosure.

The electroluminescent device provided in the present disclosure includes an anode, a light emitting layer, and a cathode, wherein the light emitting layer is located between the anode and the cathode and includes an inorganic luminescent nanomaterial and a polyimide polymer.

In general, the polyimide polymer in the light emitting layer includes at least one repeating unit represented by general formula (I):

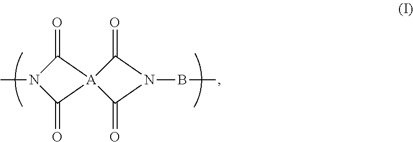

wherein A represents a tetravalent aromatic group or aliphatic group, and B represents a bivalent aromatic group or aliphatic group.

In some embodiments, the tetravalent organic group represented by A in the general formula (I) is a residue after removing two carboxylic anhydride groups (CO)₂O from tetracarboxylic dianhydride. The bivalent organic group represented by B is a residue after removing two —NH₂ groups from diamine compound. In one embodiment, the polyimide having the repeating unit represented by the general formula (I) is a polymer of the tetracarboxylic dianhydride and the diamine compound.

Examples of the tetracarboxylic dianhydride include any one of an aromatic compound and an aliphatic compound, such as an aromatic compound or a heteroaromatic compound. That is, the tetravalent organic group represented by A in the general formula (I) is an aromatic organic group or a heteroaromatic organic group.

In some embodiments, A, in multiple occurrences in the general formula (I), may be identically or differently selected from the following groups and may be further substituted:

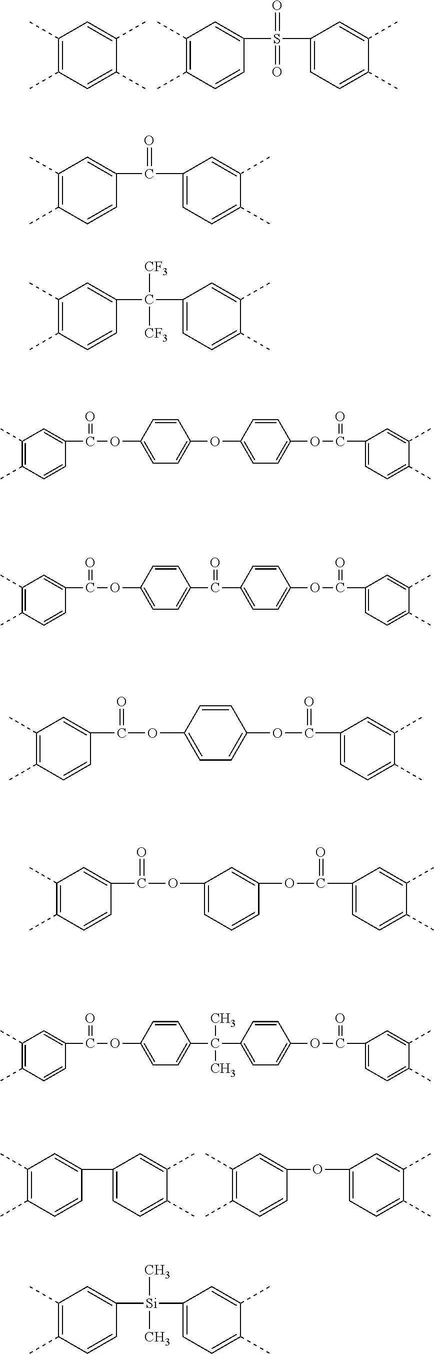

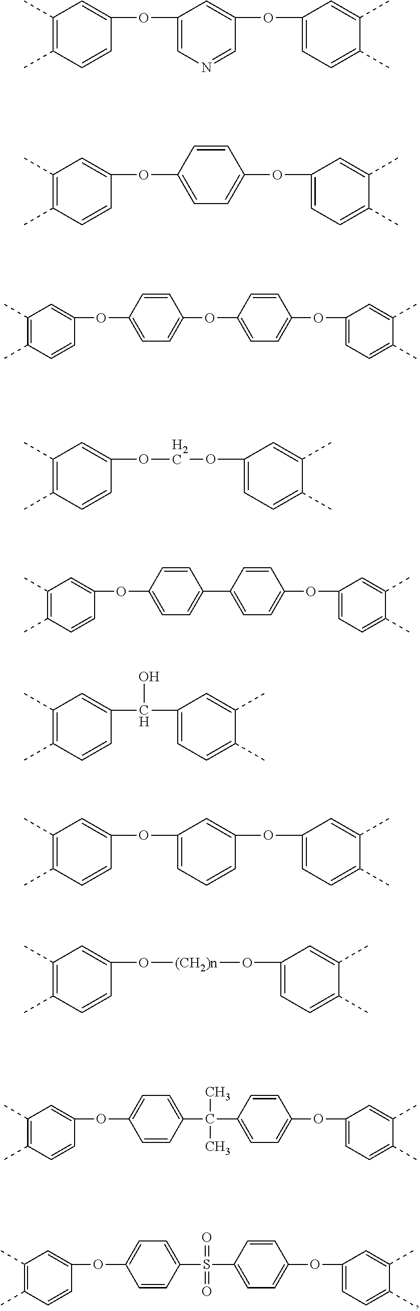

wherein the dashed line bond represents a bond linked with an adjacent structure unit.

In addition, the diamine compound refers to diamine compound having two amino groups in its molecular structure. Examples of the diamine compound include any one of an aromatic compound and an aliphatic compound, such as an aromatic compound or a heteroaromatic compound. That is, the bivalent organic group represented by B in the general formula (I) is an aromatic organic group or a heteroaromatic organic group.

In some embodiments, B, in multiple occurrences in the general formula (I), may be identically or differently selected from the following groups and may be further substituted:

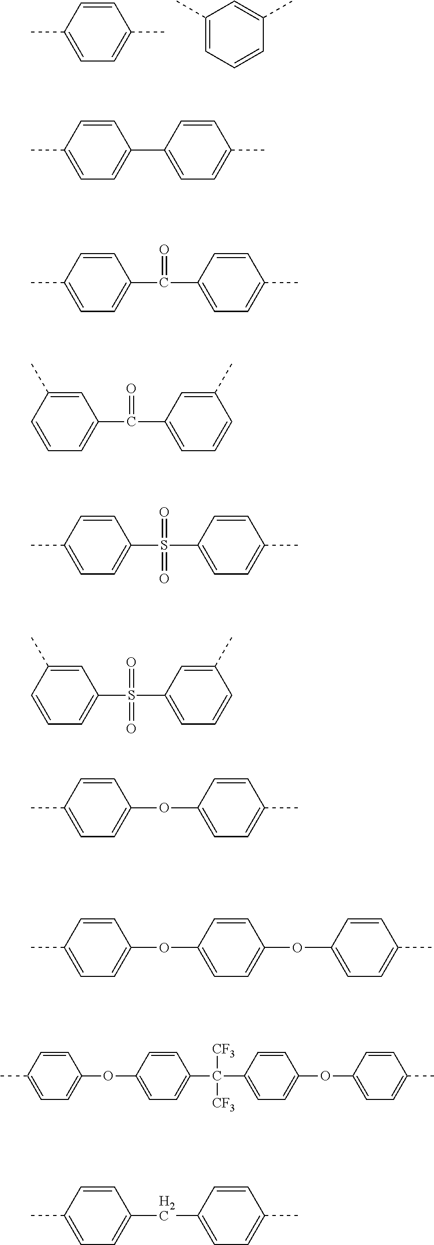

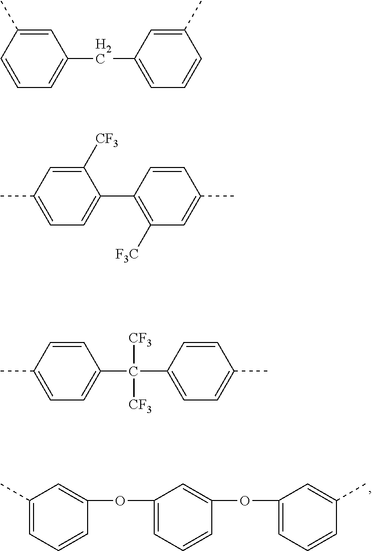

wherein the dashed line bond represents a bond linked with an adjacent structure unit.

In some embodiments, the electroluminescent device includes the polyimide polymer represented by the following general formula (II):

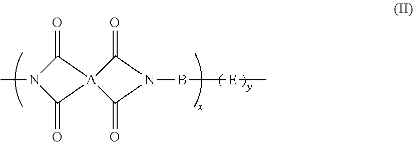

wherein A and B are defined as mentioned above, E is a group having the electron transport ability, and x+y=1.

y is in a range of 1%-30 mol %. In one embodiment, y is in a range of 5%-25 mol %. In another embodiment, y is in a range of 10%-25 mol %. In another of embodiment, y is in a range of 15%-25 mol %.

E is a functional group having the electron transport ability. Materials commonly used to transport electron in OLED may be included in the polymer of the present disclosure. In one embodiment, the functional group having the electron transport ability is selected from tris(8-quinolinolato) aluminum (AlQ₃), phenazine, phenanthroline, anthracene, phenanthrene, fluorene, bifluorene, spiro-bifluorene, p-phenylenevinylene, pyridazine, pyrazine, triazine, triazole, imidazole, quinoline, isoquinoline, quinoxaline, oxazole, isoxazole, oxadiazole, thiadiazole, pyridine, pyrazol, pyrrole, pyrimidine, acridine, pyrene, perylene, trans-indenofluorene, cis-indenofluorene, dibenzol-indenofluorene, indenonaphthalene, benzanthracene, azaphosphole, azaborole, aromatic ketone, lactam and derivatives thereof.

In another aspect, the functional group having the electron transport ability may be selected from at least one of the following structure formulas:

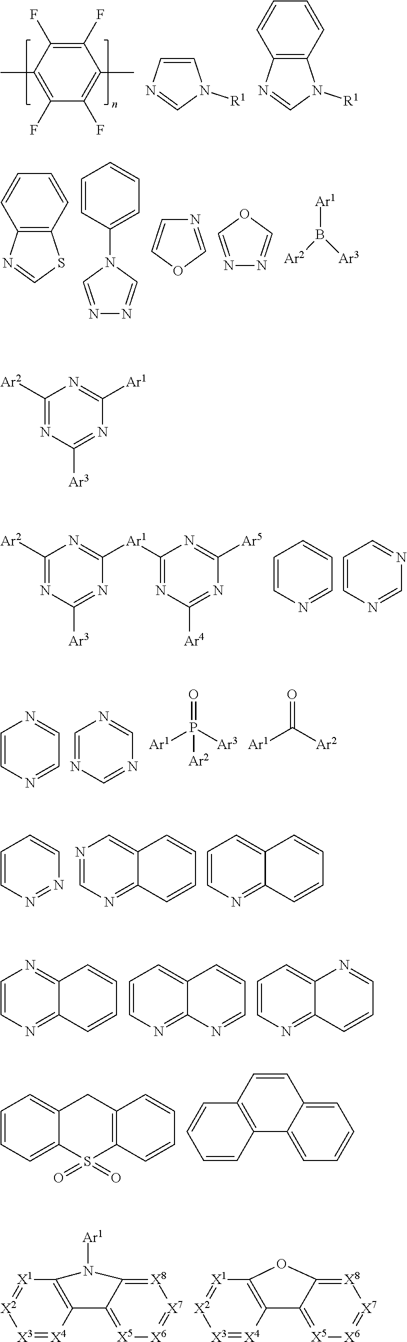

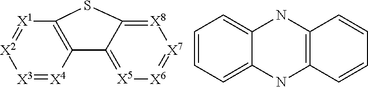

R^{I} may be selected from the following groups: hydrogen, alkyl, alkoxy, amino, alkenyl, alkynyl, aralkyl, heteroalkyl, aryl, and heteroaryl. Each of Ar¹-Ar⁵ may be independently selected from cyclic aromatic hydrocarbon compounds, such as benzene, biphenyl, triphenyl, benzo, naphthalene, anthracene, phenalene, phenanthrene, fluorene, pyrene, chrysene, perylene, azulene; aromatic heterocyclic compounds, such as dibenzothiophene, dibenzofuran, furan, thiophene, benzofuran, benzothiophene, carbazole, pyrazole, imidazole, triazole, isoxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indolizine, benzoxazole, benzisoxazole, benzothiazole, quinoline, isoquinoline, cinnoline, quinazoline, quinoxaline, naphthalene, phthalein, pteridine, xanthene, acridine, phenazine, phenothiazine, phenoxazine, dibenzoselenophene, benzoselenophene, benzofuropyridine, indolocarbazole, pyridoindole, pyrrolodipyridine, furodipyridine, benzothienopyridine, thienodipyridine, benzoselenophenepyridine and selenophenedipyridine; and groups comprising 2 to 10 ring structures, which may be the same or different cyclic aromatic groups or cyclic heteroaromatic groups and may be linked to each other directly or by at least one of the following groups, such as oxygen atom, nitrogen atom, sulfur atom, silicon atom, phosphorus atom, boron atom, chain structure unit, and alicyclic group, wherein each of Ar¹-Ar⁵ may be further substituted and the substituents may be selected from hydrogen, alkyl, alkoxy, amino, alkenyl, alkynyl, aralkyl, heteroalkyl, aryl and heteroaryl. n is an integer from 0 to 20. X¹-X⁸ are selected from CR¹ or N.

In some embodiments, the HOMO energy level of the polyimide polymer is smaller than or equal to −5.6 eV. In some embodiments, the HOMO energy level of the polyimide polymer is smaller than or equal to −5.7 eV. In some embodiments, the HOMO energy level of the polyimide polymer is smaller than or equal to −5.8 eV. In some embodiments, the HOMO energy level of the polyimide polymer is smaller than or equal to −5.9 eV. In some embodiments, the HOMO energy level of the polyimide polymer is smaller than or equal to −6.0 eV.

The valence band energy level of the inorganic quantum dot is usually in a range from −6.0 ev to −7.0 eV. The polyimide with the deeper HOMO energy level is benefit for decreasing the injection barrier between the hole transport material and the quantum dot material and benefit for the charge transport balance of the device, therefore improve the device efficiency.

In some embodiments, in the luminescent device, the HOMO energy level of the polyimide polymer and the valence band energy level V_{B} of the inorganic luminescent nanomaterial satisfy: V_{B}(inorganic luminescent nanomaterial)≤HOMO(polyimide)+0.3 eV. In some embodiments, V_{B}(inorganic luminescent nanomaterial)≤HOMO(polyimide)+0.2 eV. In some embodiments, V_{B}(inorganic luminescent nanomaterial)≤HOMO(polyimide)+0.1 eV. In some embodiments, V_{B}(inorganic luminescent nanomaterial)≤HOMO(polyimide).

In some embodiments, the average particle size of the inorganic nanomaterial is in a range from about 1 nm to 1000 nm. In some embodiments, the average particle size of the inorganic nanomaterial is in a range from about 1 nm to 100 nm. In some embodiments, the average particle size of the inorganic nanomaterial is in a range from about 1 nm to 20 nm, in some embodiments, the average particle size of the inorganic nanomaterial is in a range from 1 nm to 10 nm.

The inorganic nanomaterial may be selected from various shapes including, but are not limited to, various nano-morphologies such as sphere, cubic shape, rod shape, disk shape, or branched structure, and mixtures of particles with various shapes.

In one embodiment, the inorganic nanomaterial is a quantum dot material with very narrow and monodispersed size distribution, that is the size difference between the particles is very small. In one embodiment, the root-mean-square of size deviation of the monodispersed quantum dots is smaller than 15% rms. In another embodiment, the root-mean-square of size deviation of the monodispersed quantum dots is smaller than 10% rms. In another embodiment, the root-mean-square of size deviation of the monodispersed quantum dots is smaller than 5% rms.

In one embodiment, the inorganic nanomaterial is a luminescent material.

In some more embodiments, the inorganic luminescent nanomaterial is a quantum dot luminescent material.

The luminescent quantum dots usually may emit light in wavelengths ranged from 380 nm to 2500 nm. For example, it has been found that the emission wavelength of the quantum dot having a CdS core is in a range from about 400 nm to about 560 nm, the emission wavelength of the quantum dot having a CdSe core is in a range from about 490 nm to about 620 nm, the emission wavelength of the quantum dot having a CdTe core is in a range from about 620 nm to about 680 nm, the emission wavelength of the quantum dot having a InGaP core is in a range from about 600 nm to about 700 nm, the emission wavelength of the quantum dot having a PbS core is in a range from about 800 nm to about 2500 nm, the emission wavelength of the quantum dot having a PbSe core is in a range from about 1200 nm to about 2500 nm, the emission wavelength of the quantum dot having a CuInGaS core is in a range from about 600 nm to about 680 nm, the emission wavelength of the quantum dot having a ZnCuInGaS core is in a range from about 500 nm to about 620 nm, and the emission wavelength of the quantum dot having a CuInGaSe core is in a range from about 700 nm to about 1000 nm.

In one embodiment, the quantum dot material includes at least one material capable of emitting blue light having the emission peak wavelength ranged from 450 nm to 460 nm, or green light having the emission peak wavelength ranged from 520 nm to 540 nm, or red light having the emission peak wavelength ranged from 615 nm to 630 nm, or combinations thereof.

The included quantum dots may be selected from quantum dots having special chemical formulation, morphology structure, and/or size dimension to emit the required wavelength light under electrical stimulation. The relationship between the luminescent property of the quantum dots and the chemical formulation, the morphology structure, and/or the size dimension of the quantum dots may refer to Annual Review of Material Sci., 2000, 30, 545-610; Optical Materials Express., 2012, 2, 594-628; and Nano Res, 2009, 2, 425-447, all contents of which are specially incorporated herein by reference.

The quantum dot may have narrower luminescent spectrum because of its narrow size distribution (J. Am. Chem. Soc., 1993, 115, 8706; US 20150108405). In addition, according to different chemical formulations and structures, the size of the quantum dot should be adjusted in the above size range to obtain the luminescent property with required wavelength.

In one embodiment, the luminescent quantum dot is a semiconductor nanocrystal. In one embodiment, the size of the semiconductor nanocrystal is in a range from about 5 nm to about 15 nm. In addition, according to different chemical formulation and structures, the size of the quantum dot should be adjusted in the size range described above to obtain the luminescent property with the required wavelength.

The semiconductor nanocrystal includes at least one semiconductor material, which may be selected from a binary semiconductor compound or a multinary semiconductor compound of Group IV, Group II-VI, Group II-V, Group Group Group IV-VI, Group Group II-IV-VI, Group II-IV-V of the Periodic Table of the Elements, or mixtures thereof. The specific examples of the semiconductor material include, but are not limited to, semiconductor compounds of Group IV elements, including elementary substance such as Si and Ge, and binary compounds such as SiC and SiGe; semiconductor compounds of Group II-VI elements, including binary compounds such as CdSe, CdTe, CdO, CdS, CdSe, ZnS, ZnSe, ZnTe, ZnO, HgO, HgS, HgSe, HgTe, ternary compounds such as CdSeS, CdSeTe, CdSTe, CdZnS, CdZnSe, CdZnTe, CgHgS, CdHgSe, ZnSeS, ZnSeTe, ZnSTe, HgSeS, HgSeTe, HgSTe, HgZnS, HgSeSe, and quaternary compounds such as CgHgSeS, CdHgSeTe, CgHgSTe, CdZnSeS, CdZnSeTe, HgZnSeTe, HgZnSTe, CdZnSTe, HgZnSeS; semiconductor compounds of Group elements including binary compounds such as AlN, AlP, AlAs, AlSb, GaN, GaP, GaAs, GaSb, InN, InP, InAs, InSb, ternary compounds such as AlNP, AlNAs, AlNSb, AlPAs, AlPSb, GaNP, GaNAs, GaNSb, GaPAs, GaPSb, InNP, InNAs, InNSb, InPAs, InPSb, and quaternary compounds such as GaAlNAs, GaAlNSb, GaAlPAs, GaInNP, GaInNAs, GaInNSb, GaInPAs, GaInPSb, InAlNP, InAlNAs, InAlNSb, InAlPAs, InAlPSb; semiconductor compounds of Group IV-VI elements including binary compounds such as SnS, SnSe, SnTe, PbSe, PbS, PbTe, ternary compounds such as SnSeS, SnSeTe, SnSTe, SnPbS, SnPbSe, SnPbTe, PbSTe, PbSeS, PbSeTe, and quaternary compounds such as SnPbSSe, SnPbSeTe, SnPbSTe.

In one embodiment, the luminescent quantum dot includes semiconductor material of Group II-VI elements, such as CdSe, CdS, CdTe, ZnO, ZnSe, ZnS, ZnTe, HgS, HgSe, HgTe, CdZnSe and any combinations thereof. In one appropriate embodiment, CdSe and CdS are used as the luminescent quantum dot of visible light because of their mature preparations.

In another embodiment, the luminescent quantum dot includes semiconductor material of Group III-V elements , such as InAs, InP, InN, GaN, InSb, InAsP, InGaAs, GaAs, GaP, GaSb, AlP, AlN, AlAs, AlSb, CdSeTe, ZnCdSe, and any combinations thereof.

In another embodiment, the luminescent quantum dot includes semiconductor material of Group IV-VI elements such as PbSe, PbTe, PbS, PbSnTe, Tl₂SnTe₅, and any combinations thereof.

In one embodiment, the quantum dot has a core-shell structure. The core and the shell respectively identically or differently include one or more semiconductor materials.

The core of the quantum dot may be selected from the above described binary semiconductor compounds or multinary semiconductor compounds of Group IV, Group II-VI, Group II-V, Group III-V, Group Group IV-VI, Group Group II-IV-VI, Group II-IV-V of the Periodic Table of the Elements. The special examples for the core of the quantum dot include, but are not limited to, ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InSb, AlAs, AlN, AlP, AlSb, PbO, PbS, PbSe, PbTe, Ge, Si, and alloy or mixture of any combinations thereof.

The semiconductor material of the shell of the quantum dot may be the same or different with the core, which includes the binary semiconductor compound or the multinary semiconductor compound of Group IV, Group II-VI, Group II-V, Group III-V, Group Group IV-VI, Group Group II-IV-VI, or Group II-IV-V of the Periodic Table of the Elements. The special examples for the shell of the quantum dot include, but are not limited to, ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InSb, AlAs, AlN, AlP, AlSb, PbO, PbS, PbSe, PbTe, Ge, Si, and alloy or mixture of any combinations thereof.

In the quantum dot having the core-shell structure, the shell can be single-layer structure or a multi-layer structure. The shell includes one or more semiconductor materials identical to or different from the core. In one embodiment, the shell has the thickness of 1 to 20 layers. In another embodiment, the shell has the thickness of 5 to 10 layers. In some embodiments, the core of quantum dot has a surface with two or more shells grown thereon.

In one embodiment, the semiconductor material used in the shell has a band gap larger than that of the semiconductor material used in the core. In one embodiment, the shell and the core have type I semiconductor heterojunction structure.

In another embodiment, the semiconductor material used in the shell has a band gap smaller than that of the semiconductor material used in the core.

In one embodiment, the semiconductor material used in the shell has the atomic crystal structure same with or similar to that of the semiconductor material used in the core, which is benefit to reduce the stress between the shell and the core to make the quantum dot more stable.

The suitable examples of the luminescent quantum dot having the core-shell structure include, but are not limited to:

red light: CdSe/CdS, CdSe/CdS/ZnS, CdSe/CdZn, and etc.;

green light: CdZnSe/CdZnS, CdSe/ZnS, and etc.;

blue light: CdS/CdZnS, CdZnS/ZnS, and etc.

In one embodiment, the method for preparing the quantum dot is the colloidal growth method. In one embodiment, the method for preparing the monodispersed quantum dot is selected from hot-inject method and/or heating up method. The preparing methods are included in the document Nano Res, 2009, 2, 425-447 and Chem. Mater., 2015, 27 (7), 2246-2285, all contents of which are specially incorporated herein by reference.

In one embodiment, the surface of the quantum dot includes an organic ligand, which can control the growth process of the quantum dot, regulate the morphology of the quantum dot, and reduce surface defects of the quantum dot, thereby improving the emission efficiency and stability of the quantum dot. The organic ligand may be selected from pyridine, pyrimidine, furan, amine, alkyl phosphine, alkyl phosphine oxide, alkyl phosphonic acid or alkyl phosphinic acid, alky thiol, and etc. A specific example of the organic ligand includes, but is not limited to, tri-n-octyl phosphine, tri-n-octyl phosphine oxide, trihydroxypropyl phosphine, tributyl phosphine, tri(dodecyl) phosphine, dibutyl phosphite, tributyl phosphite, octadecyl phosphite, trilauryl phosphate, tridodecyl phosphite, triisodecyl phosphite, bis(2-ethylhexyl) phosphate, tri(tridecyl) phosphate, hexadecylamine, oleylamine, octadecylamine, dioctadecylamine, trioctadecylamine, bis(2-ethylhexyl)amine, octylamine, dioctylamine, trioctylamine, dodecylamine, didodecylamine, tridodecylamine, cetylamine, phenyl phosphonic acid, hexyl phosphonic acid, tetradecyl phosphonic acid, octyl phosphonic acid, n-octadecyl phosphonic acid, propylene diphosphonic acid, dioctyl ether, diphenyl ether, octanethiol, and dodecanethiol.

In another embodiment, the surface of the quantum dot includes an inorganic ligand. The quantum dot protected by the inorganic ligand may be obtained by ligand exchange with the organic ligand on the surface of the quantum dot. The specific examples of the inorganic ligand include, but are not limited to, S²⁻, HS⁻, Se²⁻, HSe⁻, Te²⁻, HTe⁻, TeS₃²⁻, OFF, NH₂⁻, PO₄³⁻, MoO₄²⁻, and etc. The examples of the inorganic ligand may refer to the documents J. Am. Chem. Soc. 2011, 133, 10612-10620 and ACS Nano, 2014,9,9388-9402, all contents of which are specially incorporated herein by reference.

In some embodiments, the surface of the quantum dot has one or more same or different ligands.

In one embodiment, the luminescence spectrum of the monodispersed quantum dots has the symmetrical peak shape and the narrow FWHM. In general, the better the monodispersity of the quantum dots, the more symmetrical the luminescence peak, and the narrower the FWHM. In one embodiment, the FWHM of the luminescence spectrum of the quantum dot is smaller than 70 nm. In another embodiment, the FWHM of the luminescence spectrum of the quantum dot is smaller than 40 nm. In another embodiment, the FWHM of the luminescence spectrum of the quantum dot is smaller than 30 nm.

In general, the luminescence quantum efficiency of the quantum dot is larger than 10%. In one embodiment, the luminescence quantum efficiency of the quantum dot is larger than 50%. In another embodiment, the luminescence quantum efficiency of the quantum dot is larger than 60%. In another embodiment, the luminescence quantum efficiency of the quantum dot is larger than 70%.

Other materials, technologies, methods, applications, and information which are relevant to the quantum dot and might be useful to the present disclosure are described in the following patent documents: WO2007/117698, WO2007/120877, WO2008/108798, WO2008/105792, WO2008/111947, WO2007/092606, WO2007/117672, WO2008/033388, WO2008/085210, WO2008/13366, WO2008/063652, WO2008/063653, WO2007/143197, WO2008/070028, WO2008/063653, U.S. Pat. No. 6,207,229, 6,251,303, 6,319,426, 6,426,513, 6,576,291, 6,607,829, 6,861,155, 6,921,496, 7,060,243, 7,125,605, 7,138,098, 7,150,910, 7,470,379, 7,566,476, WO2006134599A1, all contents of which are specially incorporated herein by reference.

In another embodiment, the luminescent semiconductor nanocrystal is a nanorod whose property is different from that of the sphere nanocrystal. For example, the emission of the nanorod is polarized along the long axis of the nanorod, and the emission of the sphere nanocrystal particle is not polarized (referring to Banin et al, Adv. Mater. 2002, 14, 317). In addition, the emission of the nanorod may be reversibly on and off by controlling the external electric field (referring to Banin et al., Nano Lett. 2005, 5, 1581). Those properties of the nanorod may be combined into the device of the present disclosure. Examples to prepare the semiconductor nanorod may be referred to WO03097904A1 , US2008188063A1 , US2009053522A1 , KR20050121443A, all contents of which are specially incorporated into herein by reference.

In another embodiments, the inorganic luminescent nanomaterial is luminescent perovskite nanoparticle material.

The perovskite nanoparticle material may have a general formula of AMX₃, wherein A includes organic amine or alkali metal cations, M includes metal cations, and X includes anion having oxygen or halogen anions. Specific examples of the perovskite nanoparticle material include, but are not limited to, CsPbCl₃, CsPb(Cl/Br)₃, CsPbBr₃, CsPb(I/Br)₃, CsPbI₃, CH₃NH₃PbCl₃, CH₃NH₃Pb(Cnr)₃, CH₃NH₃PbBr₃, CH₃NH₃Pb(I/Br)₃, CH₃NH₃PbI₃, and etc. The documents relevant to the perovskite nanoparticle material can refer to NanoLett., 2015, 15, 3692-3696; ACS Nano, 2015, 9, 4533-4542; AngewandteChemie, 2015, 127(19): 5785-5788; Nano Lett., 2015, 15 (4), 2640-2644; Adv. Optical Mater. 2014, 2, 670-678; J. Phys. Chem. Lett, 2015, 6(3): 446-450; J. Mater. Chem. A, 2015,3, 9187-9193; Inorg. Chem. 2015, 54, 740-745; RSC Adv., 2014,4, 55908-55911; J. Am. Chem. Soc., 2014, 136 (3), 850-853; Part. Part. Syst. Charact. 2015, 32(7), 709-720; and Nanoscale, 2013, 5(19): 8752-8780, all contents of which are specially incorporated herein by reference.

In some embodiments, the polyimide polymer has the light emitting function. In one embodiment, in the luminescent device, the wavelength of the emission peak of the inorganic luminescent nanomaterial is greater than that of the polyimide polymer. That is, the excited state energy of the polyimide polymer is larger than that of the inorganic luminescent nanomaterial, which is benefit to form the energy transfer system in which the energy is transferred from the polyimide polymer to the inorganic luminescent nanomaterial, thereby increasing the device efficiency. In one embodiment, the luminescence spectrum of the polyimide polymer and the luminescence spectrum of the inorganic luminescent nanomaterial are overlapped at least partially. In another embodiment, the luminescence spectrum of the polyimide polymer and the luminescence spectrum of the inorganic luminescent nanomaterial are overlapped largely. In another embodiment, the luminescence spectrum of the polyimide polymer and the luminescence spectrum of the inorganic luminescent nanomaterial are overlapped mostly or substantially totally. The wavelengths are overlapped substantially totally refers to that the difference between the wavelengths is no larger than 10 nm.

Another object of the present disclosure is to improve the processability of the OLED devices, especially to the processability of the light emitting layer, mainly to the printability of the light emitting layer by the polyimide polymer. In some embodiments, the doping ratio of the inorganic luminescent nanomaterial to the polyimide polymer is in a range from 1:99 to 99:1. In one embodiment, the percentage of the inorganic luminescent nanomaterial in the total weight is 2%-30%. In another embodiment, the percentage of the inorganic luminescent nanomaterial in the total weight is 3%-25%. In another embodiment, the percentage of the inorganic luminescent nanomaterial in the total weight is 4%-20%. In another embodiment, the percentage of the inorganic luminescent nanomaterial in the total weight is 5%-18%. It is beneficial to obtain better device property by disposing the doping ratio of the quantum dot in the above range. The present disclosure further relates to a mixture including at least one inorganic luminescent nanomaterial as described above and at least one polyimide polymer as described above.

The present disclosure further relates to an ink formulation including the inorganic luminescent nanomaterial as described above, the polyimide polymer as described above, and at least one organic solvent.

In one embodiment, the ink formulation according to the present disclosure is a solution.

In another embodiment, the ink formulation according to the present disclosure is a suspension liquid.

The viscosity and the surface tension of the ink are important parameters in the printing process. Appropriate surface tension parameter of the ink is suitable to the specific substrate and the specific printing method.

In one embodiment, the surface tension of the ink formulation according to the present disclosure at the working temperature or at 25° C. is in a range from about 19 dyne/cm to 50 dyne/cm. In another embodiment, the surface tension of the ink formulation according to the present disclosure at the working temperature or at 25° C. is in a range from about 22 dyne/cm to 35 dyne/cm. In another embodiment, the surface tension of the ink formulation according to the present disclosure at the working temperature or at 25° C. is in a range from about 25 dyne/cm to 33 dyne/cm.

In another embodiment, the viscosity of the ink formulation according to the present disclosure at the working temperature or at 25° C. is in a range from about 1 cps to 100 cps, In some embodiment, the viscosity of the ink formulation according to the present disclosure at the working temperature or at 25° C. is in a range from 1 cps to 50 cps, In some embodiment, the viscosity of the ink formulation according to the present disclosure at the working temperature or at 25° C. isin a range from 1.5 cps to 20 cps, and In some embodiment, the viscosity of the ink formulation according to the present disclosure at the working temperature or at 25° C. isin a range from 4.0 cps to 20 cps, by which the prepared ink formulation is suitable for inkjet printing.

The viscosity can be adjusted by various methods, such as by selecting the appropriate solvent and the concentration of the function material in the ink formulation. According to the ink formulation of the present disclosure including the mixture based on the inorganic luminescent nanomaterial and the polyimide polymer, the ink formulation may be conveniently adjusted in the appropriate range according to the used printing method. In general, the weight ratio of the mixture included in the ink formulation according to the present disclosure is in a range from 0.3 wt % to 30 wt %. In one embodiment, the weight ratio of the mixture included in the ink formulation according to the present disclosure is in a range from 0.5 wt % to 20 wt %. In another embodiment, the weight ratio of the mixture included in the ink formulation according to the present disclosure is in a range from 0.5 wt % to 15 wt %. In another embodiment, the weight ratio of the mixture included in the ink formulation according to the present disclosure is in a range from 0.5 wt % to 10 wt %. In another embodiment, the weight ratio of the mixture included in the ink formulation according to the present disclosure is in a range from 1 wt % to 5 wt %.

In some embodiments, according to the ink formulation of the present disclosure, the at least one organic solvent is selected from solvents based on aromatics or heteroaromatics, especially to aliphatic chain/ring substituted aromatic solvents, or aromatic ketone solvents, or aromatic ether solvents.

Examples suitable for the present disclosure are, but not limited to, the solvents based on aromatics or heteroaromatics: p-diisopropylbenzene, pentylbenzene, tetrahydronaphthalene, cyclohexyl benzene, chloronaphthalene, 1,4-dimethylnaphthalene, 3-i sopropylbiphenyl, p-cymene, dipentylbenzene, tripentylbenzene, pentyltoluene, o-xylene, m-xylene, p-xylene, o-diethylbenzene, m-diethylbenzene, p-diethylbenzene, 1,2,3,4-tetramethylbenzene, 1,2,3,5-tetramethylbenzene, 1,2,4,5-tetramethylbenzene, butylbenzene, dodecylbenzene, dihexylbenzene, dibutylbenzene, p-diisopropylbenzene, 1-methoxynaphthalene, cyclohexylbenzene, dimethylnaphthalene, 3-isopropylbiphenyl, p-cymene, 1-methylnaphthalene, 1,2,4-trichlorobenzene, 1,3-dipropoxybenzene, 4,4-difluorodiphenylmethane, 1,2-dimethoxy-4-(1-propenyl)benzene, diphenylmethane, 2-phenylpyridine, 3-phenylpyridine, N-methyldiphenylamine 4-isopropylbiphenyl, α, α-dichlorodiphenylmethane, 4-(3-phenylpropyl)pyridine, benzylbenzoate, 1,1′-di(3,4-dimethylphenyl)ethane, 2-isopropylnaphthalene, dibenzylether, and etc.; solvents based on ketones: 1-tetralone, 2-tetralone, 2-(phenylepoxy)tetralone, 6-(methoxyl)tetralone, acetophenone, phenylacetone, benzophenone , and derivatives thereof, such as 4-methylacetophenone, 3-methylacetophenone, 2-methylacetophenone, 4-methylphenylacetone, 3-methylphenylacetone, 2-methylphenylacetone, isophorone, 2,6,8-trimethyl-4-nonanone, fenchone, 2-nonanone, 3-nonanone, 5-nonanone, 2-demayone, 2,5-hexanedione, phorone, di-n-amyl ketone; aromatic ether solvents: 3-phenoxytoluene, butoxybenzene, benzylbutylbenzene, p-anisaldehyde dimethyl acetal, tetrahydro-2-phenoxy-2H-pyran, 1,2-dimethoxy 4-(1-propenyl)benzene, 1,4-benzodioxane, 1,3-dipropylbenzene, 2,5-dimethoxytoluene, 4-ethylphenetole, 1,2,4-trimethoxybenzene, 4-(1-propenyl)-1,2-dimethoxybenzene, 1,3-dimethoxybenzene, glycidyl phenyl ether, dibenzyl ether, 4-tert-butylanisole, trans-p-propenylanisole, 1,2-dimethoxybenzene, 1-methoxynaphthalene, diphenyl ether, 2-phenoxymethyl ether, 2-phenoxytetrahydrofuran, ethyl-2-naphthyl ether, pentyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, tetraethylene glycol dimethyl ether; and ester solvents: alkyl octoate, alkyl sebacate, alkyl stearate, alkyl benzoate, alkyl phenylacetate, alkyl cinnamate, alkyl oxalate, alkyl maleate, alkyl lactone, alkyl oleate, and etc.

Furthermore, according to the ink formulation of the present disclosure, the at least one organic solvent may be selected from aliphatic ketones, such as 2-nonanone, 3-nonanone, 5-nonanone, 2-demayone, 2,5-hexanedione, 2,6,8-trimethyl-4-demayone, phorone, di-n-pentyl ketone, and etc.; or aliphatic ethers, such as amyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethyl ether alcohol ethyl methyl ether, triethylene glycol butyl methyl ether, tripropylene glycol dimethyl ether, tetraethylene glycol dimethyl ether, and etc.

In another embodiment, the ink formulation further includes another organic solvent. Examples of the another organic solvent include, but are not limited to, methanol, ethanol, 2-methoxyethanol, dichloromethane, trichloromethane, chlorobenzene, o-dichlorobenzene, tetrahydrofuran, anisole, morpholine, toluene, o-xylene, m-xylene, p-xylene, 1,4-dioxane, acetone, methyl ethyl ketone, 1,2-dichloroethane, 3-phenoxy toluene, 1,1,1-trichloroethane, 1,1,2,2-tetrachloroethane, ethyl acetate, butyl acetate, dimethylformamide, dimethylacetamide, dimethyl sulfoxide, tetrahydronaphthalene, decalin, indene, and/or mixtures thereof.

The present disclosure further relates to the application of the ink formulation as the paint or the printing ink to make an electron device, such as by a printing method or a coating method.

The appropriate printing technology or coating technology includes, but is not limited to inkjet printing, typography, screen printing, dip coating, spin coating, blade coating, roller printing, twist roller printing, lithography, flexography, rotary printing, spray coating, brush coating or transfer printing, slot die coating, and etc. The first preference is inkjet printing, screen printing, and typography. The solution or the suspension liquid may further includes one or more components, such as a surfactant compound, a lubricant, a wetting agent, a dispersant, a hydrophobic agent, a binder, to adjust the viscosity and the film forming property and to improve the adhesion property. The detailed information relevant to the printing technology and requirements of the printing technology to the solution, such as solvent, concentration, and viscosity, may be referred to Handbook of Print Media: Technologies and Production Methods, Helmut Kipphan, ISBN 3-540-67326-1.

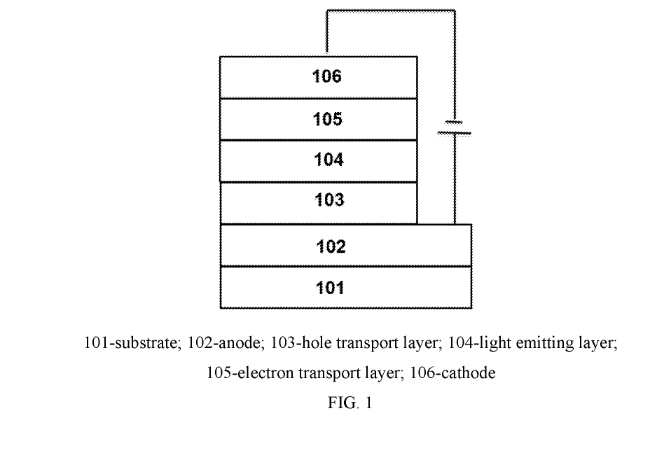

In one embodiment, the above described electronic device is an electroluminescent device. As shown in FIG. 1, the electroluminescent device includes a substrate 101, an anode 102, at least one light emitting layer 104, and a cathode 106. The substrate 101 may be opaque or transparent. The transparent substrate may be used to make the transparent luminescent device, which may be referred to, for example, Bulovic et al., Nature, 1996, 380, page 29 and Gu et al., Appl. Phys. Lett., 1996, 68, page2606. The substrate may be rigid or flexible. The substrate may be plastic, metal, a semiconductor wafer, or glass. In one embodiment, the substrate has a smooth surface. The substrate without any surface defects is the particular ideal selection. In one embodiment, the substrate may be selected from a polymer thin film or a plastic which have the glass transition temperature Tg larger than 150° C., such as larger than 200° C., larger than 250° C., and larger than 300° C. Suitable examples of the substrate are polyethylene terephthalate (PET) and polyethylene 2,6-naphthalate (PEN).

The anode 102 may include a conductive metal or metallic oxide, or a conductive polymer. The anode can inject holes easily into the hole injection layer (HIL), the hole transport layer (HTL), or the light emitting layer. In one embodiment, the absolute value of the difference between the work function of the anode and the HOMO energy level or the valence band energy level of the p type semiconductor material as the HIL or the HTL is smaller than 0.5 eV, such as smaller than 0.3 eV, and smaller than 0.2 eV. Examples of the anode material include, but are not limited to Al, Cu, Au, Ag, Mg, Fe, Co, Ni, Mn, Pd, Pt, ITO, aluminum-doped zinc oxide (AZO), and etc. Other suitable anode materials are known and may be easily selected by one of ordinary skilled in the art. The anode material may be deposited by any suitable technologies, such as the suitable physical vapor deposition method which includes a radio frequency magnetron sputtering, a vacuum thermal evaporation, an electron beam, and etc.

In some embodiments, the anode is patterned and structured. A patterned ITO conductive substrate may be purchased from market to prepare the device according to the present disclosure.

The cathode 106 may include a conductive metal or metal oxide. The cathode can inject electrons easily into the electron injection layer (EIL) or the electron transport layer (ETL), or directly injected into the light emitting layer. In one embodiment, the absolute value of the difference between the work function of the cathode and the LUMO energy level or the valence band energy level of the n type semiconductor material as the EIL or the ETL is smaller than 0.5 eV, such as smaller than 0.3 eV and smaller than 0.2 eV. In principle, all materials capable of using as the cathode of the OLED may be used as the cathode material of the device of the present disclosure. Examples of the cathode material include, but are not limited to, Al, Au, Ag, Ca, Ba, Mg, LiF/Al, MgAg alloy, BaF₂/Al, Cu, Fe, Co, Ni, Mn, Pd, Pt, ITO, and etc. The cathode material may be deposited by any suitable technologies, such as the suitable physical vapor deposition method which includes a radio frequency magnetron sputtering, a vacuum thermal evaporation, an electron beam, and etc.

The light emitting layer 104 includes at least one luminescent nanomaterial, whose thickness may be in a range from 2 nm to 200 nm. In one embodiment, in the luminescent device according to the present disclosure, the light emitting layer includes the mixture of the inorganic luminescent nanomaterial and the polyimide polymer, whose thickness is for example in a range from 5 nm to 100 nm, such as in a range from 15 nm to 80 nm.

In one embodiment, the luminescent device according to the present disclosure further includes the hole injection layer (HIL) or the hole transport layer (HTL) 103, which includes an organic hole transport material (HTM) or an inorganic p type material.

The suitable organic hole injection material (HIM)/hole transport material (HTM) may be selected from compounds including the following structure units: phthalocyanine, porphyrin, amine, aromatic amine, biphenyl triarylamine, thiophene, fused thiophene such as dithienothiophene and fused thiophene, pyrrole, aniline, carbazole, indolocarbazole and derivatives thereof. In addition, the suitable HIM also includes polymer containing fluorocarbon, polymer containing conductive dopant, conductive polymer, such as PEDOT/PSS, a self-assembly monomer, such as a compound containing phosphonic acid and sliane derivative, metal oxide, such as MoOₓ, metal complex, a crosslinking compound, and etc.

The suitable inorganic p type semiconductor is selected from metal oxide, chalcogenide, semiconductor of Group IV elements, semiconductor of Group II-VI elements, semiconductor of Group III-V elements, and semiconductor of Group IV-VI elements, any alloy thereof, and/or a mixture including any of the former alloys. Typical examples include, but are not limited to, NiO, Cu₂O, Cr₂O₃, MoO₂, PbO, Hg₂O, Ag₂O, MnO, CoO, SnO, Pr₂O₃, Cu₂S, SnS, Sb₂S₃, Cul, Bi₂Te₃, Te, Se.

In another embodiment, the luminescent device according to the present disclosure further includes an electron injection layer (EIL) or an electron transport layer (ETL) 105 including the above described organic ETM or inorganic n type material.

Examples of EIM/ETM are not particularly limited. Any metal complex or organic compound may be used as EIM/ETM, as long as they can transport electrons. An organic EIM/ETM may be selected from tris(8-quinolinolato)aluminum (AlQ₃), phenazine, phenanthroline, anthracene, phenanthrene, fluorene, bifluorene, spiro-bifluorene, phenylene-vinylene, pyridazine, pyrazine, triazine, triazole, imidazole, quinoline, isoquinoline, quinoxaline, oxazole, isoxazole, oxadiazole, thiadiazole, pyridine, pyrazole, pyrrole, pyrimidine, acridine, pyrene, perylene, trans-indenofluorene, cis-indenofluorene, dibenzo-indenofluorene, indenonaphthalene, benzanthracene, azaphosphole, azaborole, aromatic ketone, lactam, and derivatives thereof.

In another embodiment, the EIM/ETM may be an inorganic n type semiconductor material.

In one embodiment, the inorganic n type semiconductor material is selected from metal oxide, semiconductor of Group IV elements, semiconductor of Group III-V elements, semiconductor of Group IV-VI elements, and semiconductor of Group II-VI elements, any alloy thereof, and/or any mixture thereof, which includes a ternary and quaternary mixture or the alloy. In one embodiment, the metal oxide includes, but is not limited to ZnO, In₂O₃, Ga₂O₃, TiO₂, MoO₃, SnO₂, and alloy thereof, such as SnO₂:Sb, In₂O₃:Sn (ITO), ZnO:Al, Zn—Sn—O, In—Zn—O, IGZO (such as InGaZnO₄, In₂Ga₂ZnO₇, InGaZnOₓ), and etc.

The present disclosure relates to an electronic device including at least one polyimide polymer according to the present disclosure.

The electronic device may be selected from organic light emitting diode (OLED), organic photovoltaic cell (OPV), organic light emitting electrochemical cell (OLEEC), organic field effect transistor (OFET), organic light emitting field effect transistor, organic laser, organic spin electron device, organic sensor, organic plasmon emitting diode, quantum dot light emitting diode (QLED), quantum dot photovoltaic cell (QPV), quantum dot light emitting electrochemical cell (QLEEC), quantum dot field effect transistor (QFET), quantum dot light emitting field effect transistor, quantum dot laser, and quantum dot sensor.

The disclosure will now be described with reference to the preferred embodiments, but the disclosure is not to be construed as being limited to the following examples. It is to be understood that the appended claims are intended to cover the scope of the disclosure. Those skilled in the art will understand that modifications may be made to various embodiments of the disclosure with the teaching of the present disclosure, which will be covered by the spirit and scope of the claims of the disclosure.

### EXAMPLES

1. Material and Energy Level

The polyimide polymer used in an embodiment of the present disclosure has the following structure formula:

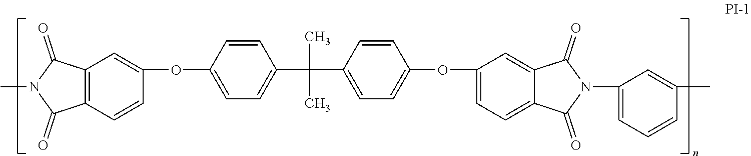

The synthetic method of the material is well-known and described in prior art, and would not be repeated here.

With respect to the compound represented by general formula (II), in one embodiment of the compound is represented by the following structure formula:

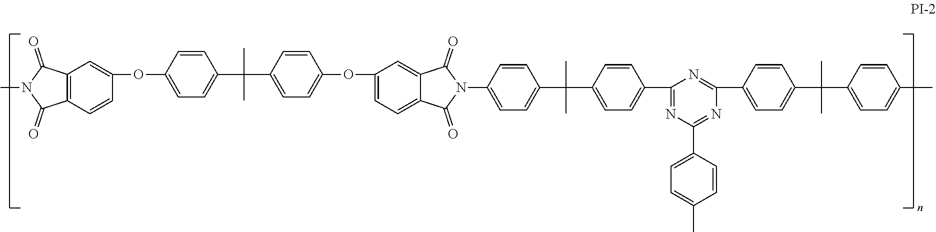

The reaction equation to synthesize the material PI-2 is shown as follows:

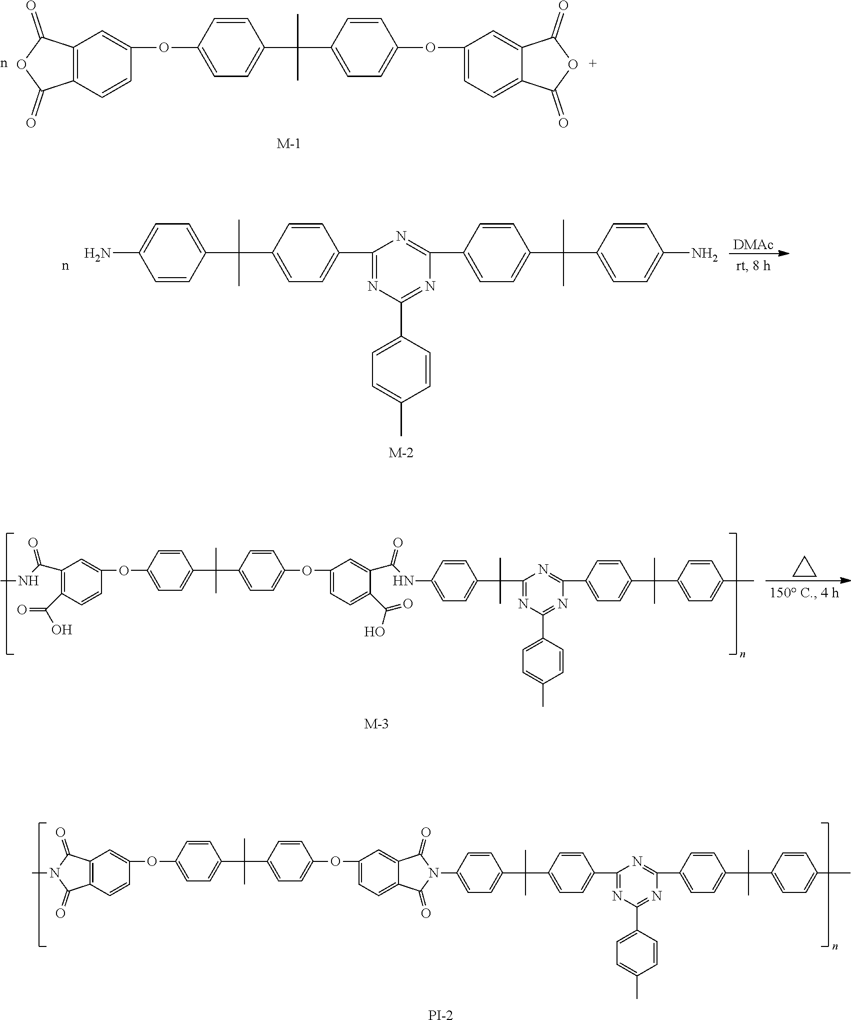

The intermediates M-1 and M-2 are purchased from the domestic intermediate manufacturer. The specific reaction steps are:

a. In a clean three-necked flask, under mechanical stirring condition, the intermediates M-1 and M-2 with the same mole concentration are dissolved into N,N-dimethylacetamide (DMAc) to mix the intermediates M-1 and M-2 uniformly. At the room temperature, the mixture is stirred for 8 hours. The reaction is kept going on without any treatment when the solution is in a viscous state, and the liquid state intermediate product M-3 is obtained.

b. The obtained intermediate product M-3 solution is heated to 150° C. to have a reaction. When pale yellow occurs and the solution is viscous, the temperature is decreased to stop the reaction. When the reaction liquid is cooled to the room temperature, DMAc solvent is removed from the reaction liquid by a reduced pressure distillation to obtain a pale yellow solid, which is then milled into powder. The powder is successively and respectively pulped by using dichloromethane and ethyl alcohol, and filtered to obtain a pale yellow solid powder PI-2.

The energy level of the organic material may be obtained by quantum computing, such as by Gaussian09W (Gaussian Inc.) using TD-DFT (Time-Dependent Density Functional Theory). The detailed simulation method may be referred to WO2011141110. First, the molecular geometry structure may be optimized by a semi-empirical method “Ground State/Semi-empirical/Default Spin/AM1” (Charge 0/Spin Singlet). Then the energy structure of the organic molecule is calculated by using the TD-DFT method for “TD-SCF/DFT/Default Spin/B3PW91” and the base group “6-31 G(d)” (Charge 0/Spin Singlet). The HOMO and LUMO energy levels are calculated according to the following calibration equations. Si and Ti are directly used.

HOMO(eV)=((HOMO(G)×27.212)−0.9899)/1.1206

LUMO(eV)=((LUMO(G)×27.212)−2.0041)/1.385

The HOMO(G) and LUMO(G) are direct computed results of Gaussian 09W, whose unit are Hartree. The detailed simulation method may be referred to WO2011141110. The polymer PI-1 and PI-2 are obtained by simulate the following tripolymers:

TABLE 1

| Matrial | HOMO [eV] | LUMO [eV] | T1 [eV] | S1 [eV] |
|---|---|---|---|---|
| PI-1 | −6.49 | −3.24 | 2.67 | 3.12 |
| PI-2 | −6.32 | −3.23 | 2.62 | 2.98 |

2. Preparation and Property of the Electroluminescent Device

The preparation process of the electroluminescent device will now be described with reference to the specific embodiments.

### Example 1

The Preparation Steps Include:

1) cleaning of the ITO transparent electrode (anode) glass substrate, wherein the substrate is ultrasonically treated for 30 minutes with an aqueous solution containing 5% of Decon90 cleaning fluid, then ultrasonically cleaned with deionized water for several times and ultrasonically cleaned with isopropanol, then blow-dried with nitrogen gas, and treated with oxygen plasma for 5 minutes to clean the ITO surface and increase the work function of the ITO electrode;

2) preparation of the hole transport layer, wherein the PEDOT:PSS solution is spin coated on the glass substrate treated with oxygen plasma to obtain a 40 nm of thin film, then annealled in a glovebox at 150° C. for 20 minutes, then 20 nm of TFB thin film (5 mg/mL of toluene solution) is spin coated on the PEDOT:PSS and treated on a hot plate at a temperature of 180° C. for 60 minutes;

wherein TFB is a hole transport material (purchased from Amerimay Dye Source, Inc) used in HTL. The structure formula of the TFB is as follows:

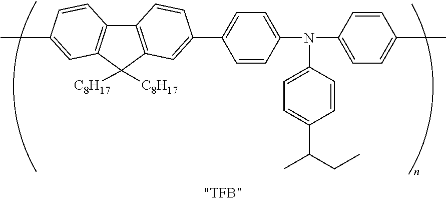

3) preparation of the quantum dot light emitting layer, wherein the quantum dot/polyimide solution is spin coated after annealing, wherein the quantum dots have CdSe/CdS core-shell structures and are dispersed into chloroform, the structure of the polyimide is represented by PI-1, the solution concentration is 5 mg/mL, and the ratio of the quantum dot to the polyimide is 80:20 (wt %).

4) preparation of the electron transport layer, wherein 40 nm of ZnO ethanol solution is spin coated after spin coating of the quantum dot solution, wherein the ZnO in the ZnO ethanol solution is made by a cryogenic fluid method, the ZnO is nano particles with the size of 5 nm, the ZnO are dispersed into ethanol to form the solution with concentration of 45 mg/mL;

5) preparation of the cathode: the spin coated device is put into a vacuum evaporation chamber, and vacuum evaporated with a silver cathode to finish the quantum dot luminescent device.

### Example 2

The preparation method of the electroluminescent device is the same as that of Example 1, except that in the quantum dot/polyimide solution used in the preparation of quantum dot light emitting layer, the ratio of the quantum dot to the polyimide is 50:50 (wt %).

### Example 3

The preparation method of the electroluminescent device is the same as that of Example 1, except that in the quantum dot/polyimide solution used in the preparation of quantum dot light emitting layer, the ratio of the quantum dot to the polyimide is 30:70 (wt %).

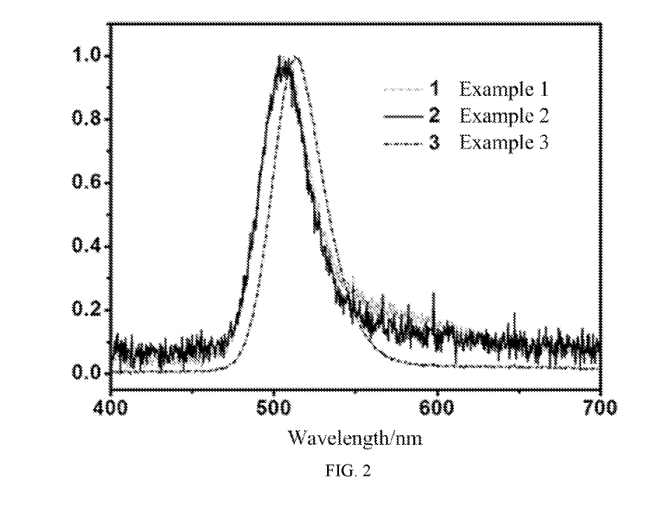

The properties of the electroluminescent devices of all examples are listed in Table 2. The electroluminescence spectrum is shown in FIG. 2.

TABLE 2

| | Turn-on voltage | maximum | Electroluminescent |
|---|---|---|---|
| | (V) | luminance (cd/m²) | peak (nm) |
| Example 1 | 4.1 | 2700 | 515 |
| Example 2 | 4.4 | 1800 | 506 |
| Example 3 | 4.9 | 1300 | 505 |

1. An electroluminescent device comprising an anode, a light emitting layer, and a cathode, wherein the light emitting layer is located between the anode and the cathode, the light emitting layer comprises an inorganic luminescent nanomaterial and a polyimide polymer.

2. The electroluminescent device of claim 1, wherein the polyimide polymer comprises a repeating unit represented by general formula (I): 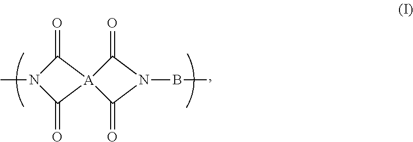
wherein A represents a tetravalent aromatic group or aliphatic group, and B represents a bivalent aromatic group or aliphatic group.

3. The electroluminescent device of claim 1, wherein the polyimide polymer comprises a repeating unit represented by general formula (II): 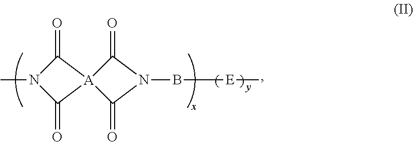
wherein A represents a tetravalent aromatic group or aliphatic group, B represents a bivalent aromatic group or aliphatic group, E is a group having an electron transport ability, and x+y=1.

4. The electroluminescent device of claim 2, wherein A, in multiple occurrences in the polyimide polymer, is identically or differently selected from following groups, and is capable of being further substituted: 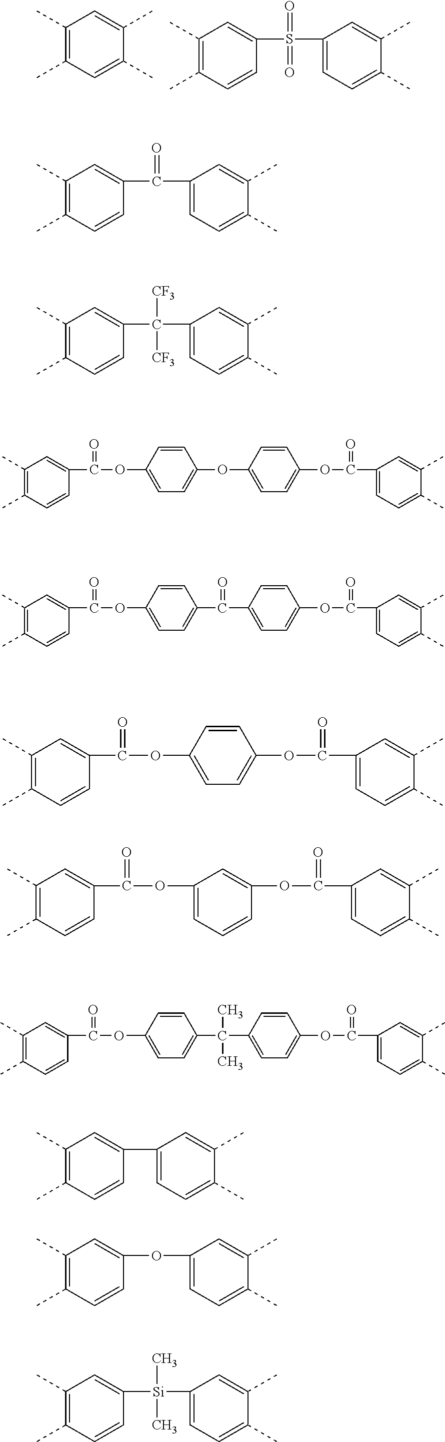 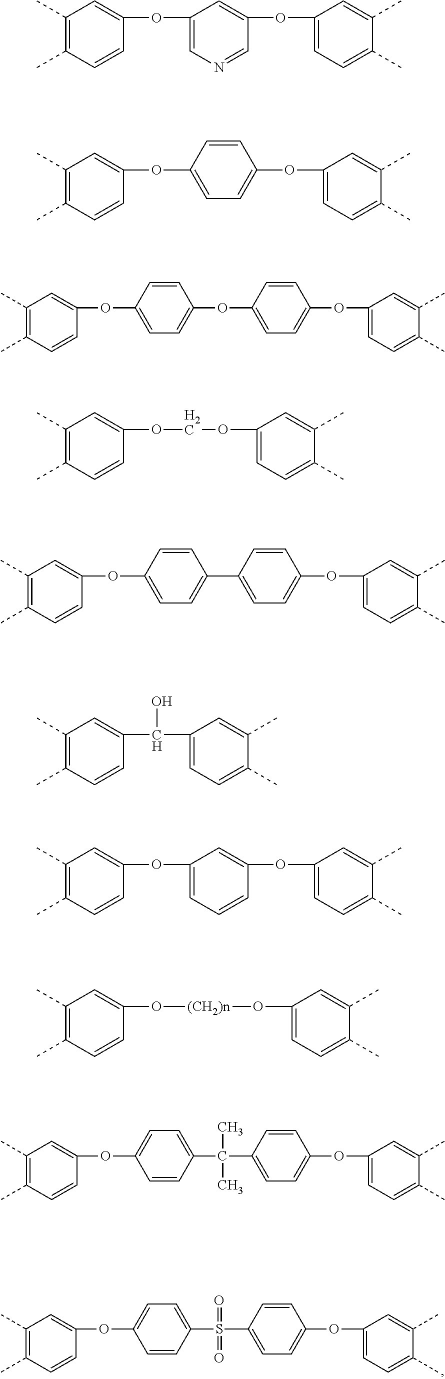
wherein the dashed line bond represents a bond linked with an adjacent structure unit.

5. The electroluminescent device of claim 2, wherein B, in multiple occurrences in the polyimide polymer, is identically or differently selected from following groups and is capable of being further substituted: 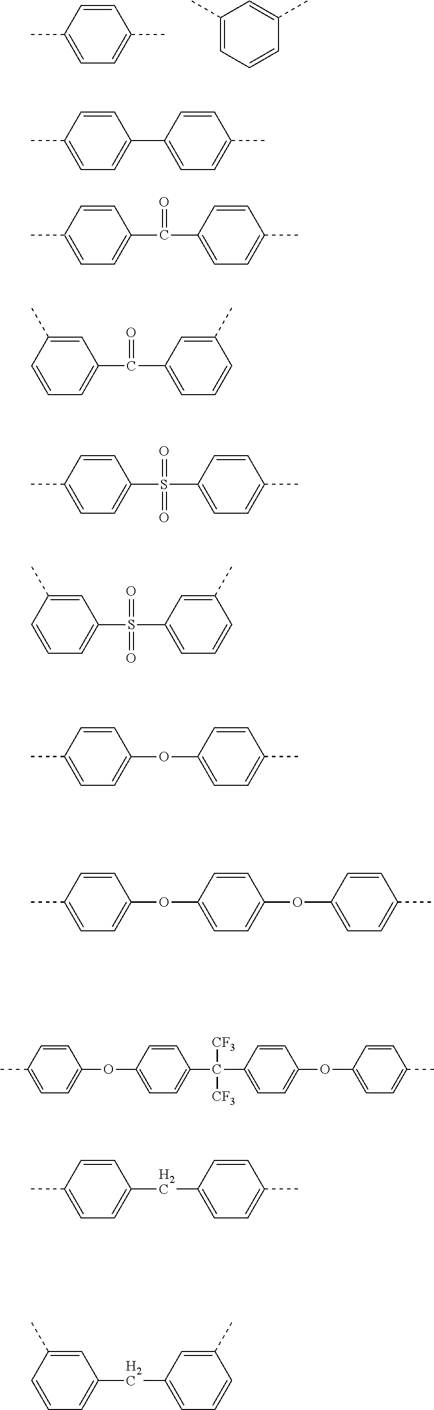 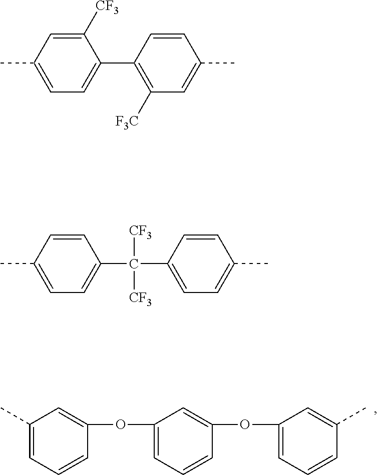
wherein shown dashed line bond represents a bond linked with an adjacent structure unit.

6. The electroluminescent device of claim 3, wherein E is selected from phenazine, phenanthroline, anthracene, phenanthrene, fluorene, bifluorene, spiro-bifluorene, p-phenylenevinylene, pyridazine, pyrazine, triazine, triazole, imidazole, quinoline, isoquinoline, quinoxaline, oxazole, isoxazole, oxadiazole, thiadiazole, pyridine, pyrazol, pyrrole, pyrimidine, acridine, pyrene, perylene, trans-indenofluorene, cis-indenofluorene, dibenzol-indenofluorene, indenonaphthalene, benzanthracene, azaphosphole, azaborole, aromatic ketone, lactam and derivatives thereof.

7. The electroluminescent device of claim 1, wherein a HOMO energy level of the polyimide polymer is smaller than or equal to −5.6 eV.

8. The electroluminescent device of claim 1, wherein a HOMO energy level of the polyimide polymer and a valence band energy level VB of the inorganic luminescent nanomaterial satisfy: VB≤HOMO+0.3 eV.

9. The electroluminescent device of claim 1, wherein an emission wavelength of the inorganic luminescent nanomaterial is in a range from 380 nm to 2500 nm.

10. The electroluminescent device of claim 1, wherein an emission peak wavelength of the inorganic luminescent nanomaterial is larger than a peak emission wavelength of the polyimide polymer.

11. The electroluminescent device of claim 1, wherein an emission peak wavelength of the inorganic lumiescent material with a monodispersed particle size distribution, and a shape of the quantum dot material is selected from a spherical nano-morphology, a cubic nano-morphology, a rodlike nano-morphology, or a branched structure nano-morphology.

12. The electroluminescent device of claim 1, wherein the inorganic luminescent nanomaterial is a binary semiconductor compound or a multinary semiconductor compound of Group IV, Group II-VI, Group II-V, Group III-V, Group Group IV-VI, Group Group II-IV-VI, or Group II-IV-V of the Periodic Table of the Elements, or mixtures thereof.

13. The electroluminescent device of claim 1, wherein the inorganic luminescent nanomaterial is a luminescent perovskite nano-particle material, a luminescent metal nano-particle material, a luminescent metal oxide nano-particle material, or mixtures thereof.

14. The electroluminescent device of claim 1, wherein a doping ratio of the inorganic luminescent nanomaterial to the polyimide polymer is in a range from 1:99 to 99:1.

15. The electroluminescent device of claim 1, wherein the electroluminescent device is selected from a quantum dot light emitting diode, a quantum dot light emitting electrochemical cell, a quantum dot light emitting field effect transistor, or a quantum dot laser.

16. An ink formulation, comprising an inorganic luminescent nanomaterial, a polyimide polymer, and at least one organic solvent.

17. The ink formulation of claim 16, wherein the polyimide polymer comprises a repeating unit represented by general formula (I): 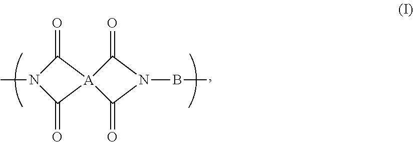
wherein A represents a tetravalent aromatic group or aliphatic group, and B represents a bivalent aromatic group or aliphatic group.

18. The ink formulation of claim 16, wherein the polyimide polymer comprises a repeating unit represented by general formula (II): 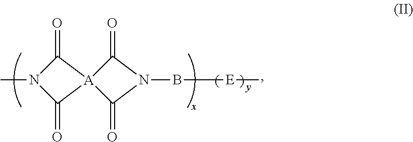
wherein A represents a tetravalent aromatic group or aliphatic group, B represents a bivalent aromatic group or aliphatic group, E is a group having an electron transport property, and x+y=1.

19. The ink formulation of claim 16, wherein a HOMO of the polyimide polymer is smaller than or equal to −5.6 eV, and the HOMO of the polyimide polymer and a valence band energy level VB of the inorganic luminescent nano-material satisfy: VB≤HOMO+0.3 eV.

20. A method for preparing the electroluminescent device of claim 1, wherein the light emitting layer is made by a printing or coating method, and the printing or coating method is selected from inkjet printing, spray printing, typography, screen printing, dip coating, spin coating, blade coating, roller printing, twist roller printing, lithography, flexography, rotary printing, spray coating, brush coating, transfer printing, or slot die coating.
